(19) United States
(12) Patent Application Publication
(10) Pub. No.: US 2006/0197417 A1
(43) Pub. Date: Sep. 7, 2006

(54) Mounting mechanism for computer enclosure

(75) Inventors: Yun-Lung Chen, Tu-Cheng (TW); Lin Ding, Shenzhen (CN); Chuan-Lin Zheng, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/193,892

(22) Filed: Jul. 29, 2005

(30) Foreign Application Priority Data
Mar. 4, 2005 (CN) 200520055503.5

(51) Int. Cl. H05K 5/00

(52) U.S. Cl. 312/223.2

(57) ABSTRACT

A computer enclosure includes a chassis (60) having a blocking portion (67) and a cover (10) attached to the chassis (60). A handle (20) having a pressing tab (26) is attached to the cover (10). A locking block (50) is locked with the blocking portion (67) to secure the cover (10) to the chassis (60). The locking block (50) includes an inclined face (53) for the pressing tab (26) sliding therealong. When the handle (20) is pulled, the locking block (50) is disengaged from the blocking portion (67) of the chassis (60).

### BACKGROUND OF THE INVENTION

1. Field of the Invention

The present invention relates to a computer enclosure, and more particularly to a mounting mechanism which facilitates assembly of a computer cover to a computer enclosure.

2. Background of the Invention

In order to mount electronic components into a computer conveniently, an opening is usually defined in a computer enclosure. The electronic components such as hard disk, CD-ROM, get through the opening and are secured therein. Then, a side plate is mounted on the computer enclosure to cover the opening.

Previously, the side plate of the computer is typically secured to the computer enclosure by retaining screws. In the process to mount or demount components in the computer enclosure, it is necessary to remove the individual retaining screw firstly. However, there are a plurality of screws fastened in the computer enclosure. It is boring to manipulate the screws frequently. Furthermore, the tiny screw will be easily lost or dropped into other electronics of the computer. If not removed carefully, the presence of a screw can cause electronic or physical damage to the computer electronics.

Accordingly, what is needed is a mounting mechanism which facilitates assembly of a computer cover to a computer enclosure.

### SUMMARY OF THE INVENTION

A computer enclosure according to a preferred embodiment of the present invention includes a chassis having a blocking portion and a cover attached to the chassis. A handle having a pressing tab is attached to the cover. A locking block is locked with the blocking portion to secure the cover to the chassis. The locking block includes an inclined face for the pressing tab sliding therealong. When the handle is pulled, the locking block is disengaged from the blocking portion of the chassis.

Other objects, advantages and novel features of the present invention will be drawn from the following detailed description of preferred embodiments of the present invention with the attached drawings, in which:

### BRIEF DESCRIPTION OF THE DRAWINGS

FIG. 1 is an exploded, isometric view of a computer enclosure in accordance with a preferred embodiment of the present invention;

FIG. 2 is a partial view of FIG. 1, and viewed from another aspect;

FIG. 3 is an assembled view of FIG. 2;

FIG. 4 is an assembled view of FIG. 1, the cover being in a released station;

FIG. 5 is a partially enlarged view of portion V in FIG. 4;

FIG. 6 is an assembled view of FIG. 1, the cover being in a locked station; and

FIG. 7 is a partially enlarged view of portion VII in FIG. 6.

### DETAILED DESCRIPTION OF THE INVENTION

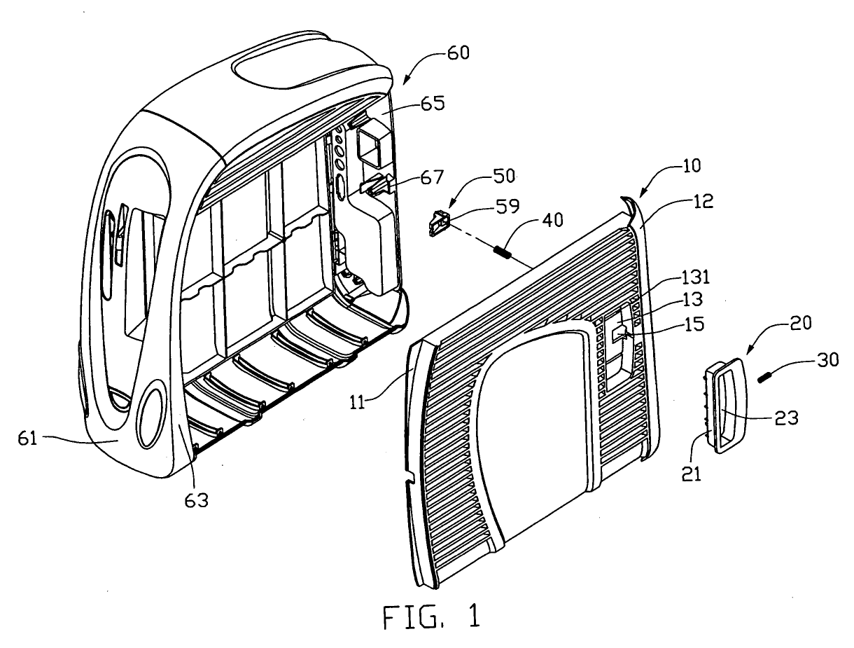

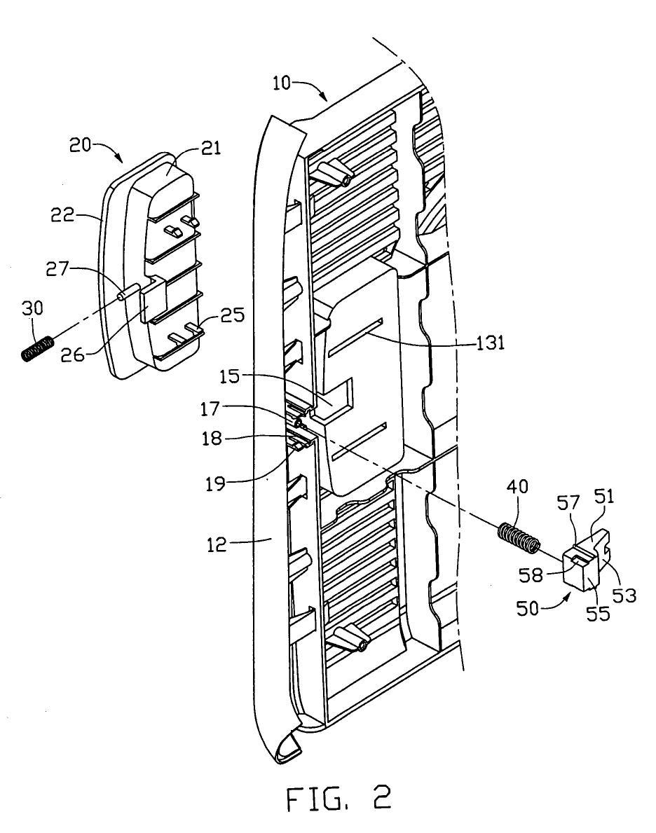

Referring to FIGS. 1 and 2, a mounting mechanism for a computer enclosure in accordance with a preferred embodiment of the present invention includes a cover 10, a handle 20 received in the cover, a locking block 50 and a chassis 60.

The cover 10 includes a flange 11 protruding from one edge and a plate 12 extending inwardly from the other. A rectangular receiving recesss 13 is defined in the cover 10. A pair of securing slots 131 are defined in the recess 13. A rectangular opening 15 is defined between the two securing slots 131. A post 17 adjacent to the opening 15 protrudes inwardly from the inner side of the cover 10. A pair of opposite hooks 19 protrudes respectively from two sides of the post 17. A sliding slot 18 is formed beside each hook 19.

The handle 20 includes a base 21 and a flange 22 formed therefrom. The base 21 sinks inwardly and forms a holding portion 23. A plurality of catches 25 corresponding to the securing slots 131 protrudes from a bottom of the base 21. An L-shaped pressing tab 26 corresponding to the opening 15 of the cover 10 extends backwardly from the bottom of the base 21. A post 27 protrudes from the side wall of the base 21. A first spring 30 is disposed around the post 27.

The locking block 50 is wedge-shaped, and includes a protuberance 55. The locking block 50 has a pair of parallel side faces 51 and an inclined face 53. A ridge 57 corresponding to the sliding slot 18 extends through the side face 51. A securing notch 58 in correspondence with the hook 19 is defined at a corner of the side face 51. A hollow 59 is formed in the bottom of the locking block 50 for receiving one end of a second spring 40. The other end of the second spring 40 is disposed around the post 17.

The chassis 60 includes a front panel 61 and a rear panel 65. A flange 63 extends backwardly from a side edge of the front panel 61. A blocking portion 67 corresponding to the locking block 50 protrudes inwardly from the rear panel 65.

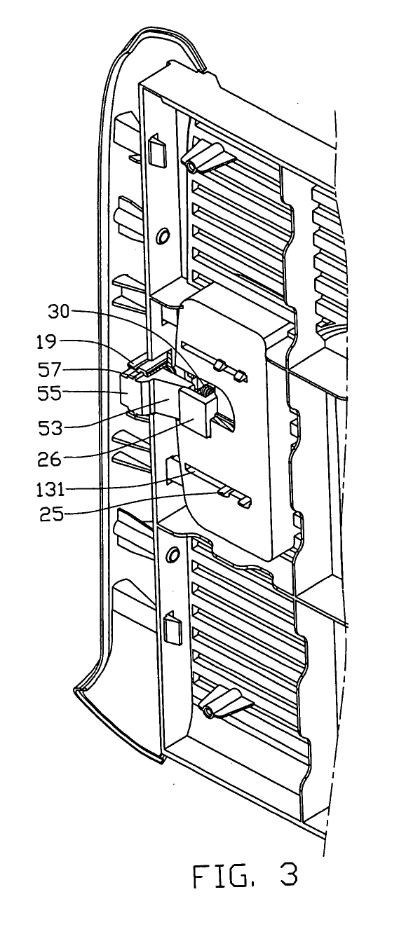

Referring to FIG. 3, one end of the second spring 40 is received in the hollow 59 and the other end is disposed around the post 17. The ridges 57 of the locking block 50 are inserted into the sliding slots 18 of the cover 10. After moving for a distance, the hooks 19 of the cover 10 are engaged into the securing notch 58 of the locking block 50. Then the locking block 50 can be slid in a range between the cover 10 and the hooks 19. Leaning the handle 20 little, the pressing tab 26 of the handle 20 gets through the opening 15 of the receiving recess 13 and touches against the inclined face 53 of the locking block 50. The catches 25 of the handle 20 protrudes through the securing slots 131 and engages therein. One end of the first spring 30 is disposed around the post 27 of the base 21 and the other end is abutted against the plate 12 of the cover 10. Thus, the handle 20 is assembled in the receiving recess 13. The handle 20 and the locking block 50 is in an initial state.

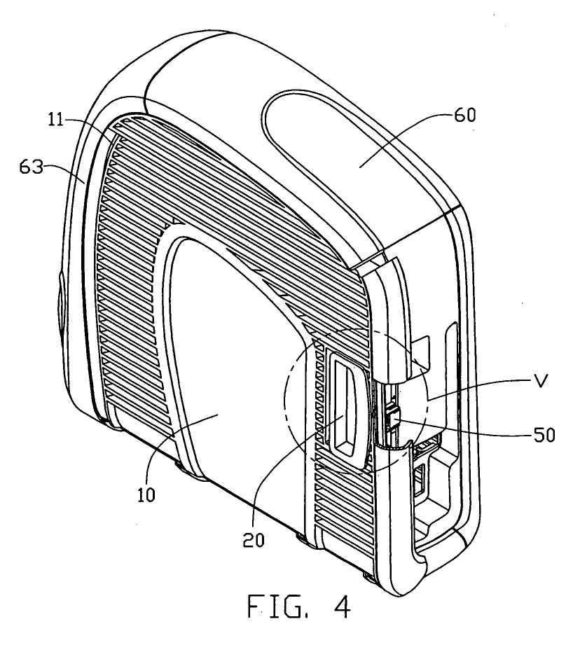

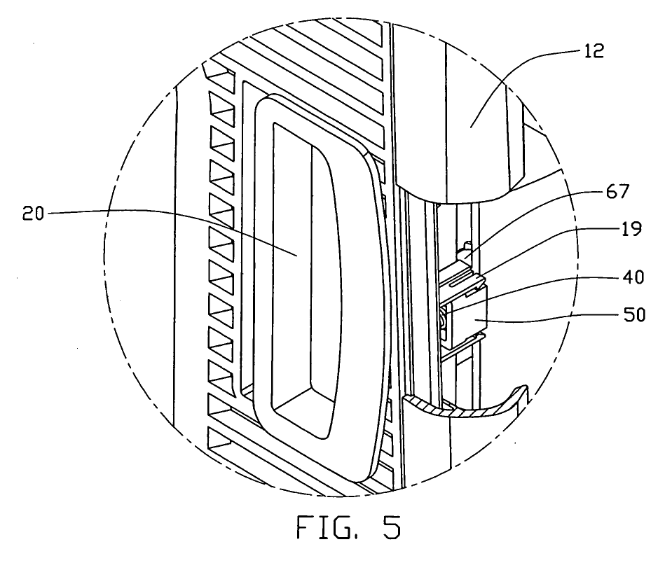

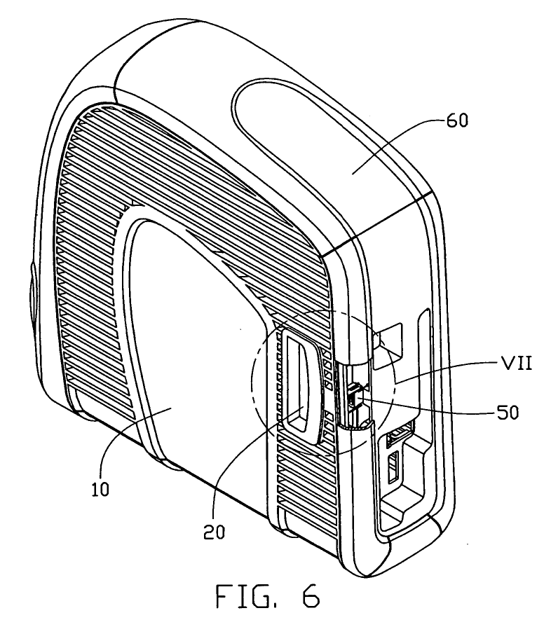

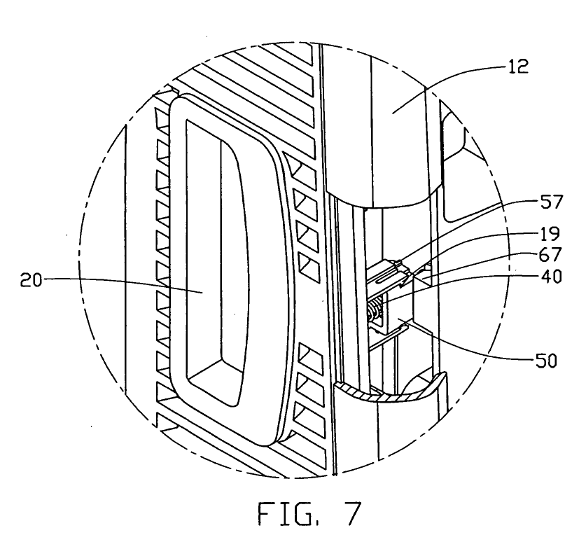

Referring to FIGS. 4-7, in assembly, pushing the cover 10 forwardly, the flange 11 of the cover 10 is inserted behind the side plate 63 of the chassis. The edge of side plate 63 abuts against the flange 11 to prevent the cover 10 further moving. While the cover 10 moving forwardly, the locking block 50 is forced to move outwardly by the blocking portion 67 of the rear panel 65. The second spring 40 is compressed. When the protuberance 55 of the locking block 50 rides over the blocking portion 67, the locking block 50 rebounds due to the spring 40. The protuberance 55 is blocked by the blocking portion 67, so that the cover 10 can not be moved back. Thus, the cover 10 is mounted on the chassis 60.

In disassembly, pulling the handle 20 backwardly in the receiving recess 13, the pressing tab 26 is slid along the inclined face 53 towards the protuberance 55 until the locking block 50 is pressed to move outwardly. The locking block 50 is retracted to avoid the blocking portion 67. Pulling the cover 10 backwardly, the cover 10 is disassembled from the chassis 60. At this time, the handle 20 and the locking block 50 come back to the initial state respectively for the next operation due to the spring 30 and 40.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

We claim:

1. A computer enclosure comprising:
a chassis having a blocking portion;
a cover attached to the chassis;
a handle attached to the cover, the handle having a pressing tab; and
a locking block disposed on the cover, the locking block engaging with the blocking portion, thereby securing the cover to the chassis, the locking block having an inclined face for the pressing tab of the handle sliding therealong, thereby disengaging the locking block from the blocking portion of the chassis.

2. The computer enclosure as claimed in claim 1, wherein a plurality of catches protruding from a bottom of the handle, and a pair of securing slots are defined in the cover for the catches engaging therein.

3. The computer enclosure as claimed in claim 1, wherein a pair of hooks protrudes from the cover for retaining the locking block.

4. The computer enclosure as claimed in claim 3, wherein a securing notch is defined in the locking block for the hook engaging thereto.

5. The computer enclosure as claimed in claim 3, wherein a sliding slot is defined beside each hook of the cover, and a ridge corresponding to the sliding slot extends through the side face of the locking block.

6. The computer enclosure as claimed in claim 1, wherein a first spring is disposed between the handle and the cover, and a second spring is disposed between the locking block and the cover.

7. A computer enclosure comprising:
a chassis having a blocking portion;
a handle having a plurality of catches; and
a cover having a recess for receiving the handle, a pair of securing slots corresponding to the catches are defined in the recess, a spring is disposed between the handle and the cover, the cover having a locking block for engaging with the blocking portion, thereby securing the cover to the chassis, whereby when the handle is pulled to move in the securing slots, the locking block is forced by the handle to disengage from the blocking portion.

8. The computer enclosure as claimed in claim 7, wherein a pressing tab extends from the handle, and an opening is defined in the cover for the pressing tab protruding therethrough and forcing the locking block to disengage from the blocking portion.

9. The computer enclosure as claimed in claim 8, wherein the locking block has an inclined face for the pressing tab sliding therealong.

10. The computer enclosure as claimed in claim 7, wherein a post protrudes from the handle for the spring disposed around.

11. The computer enclosure as claimed in claim 10, wherein the cover comprises a plate extending from one edge thereof, and the spring is abutted against the plate.

12. The computer enclosure as claimed in claim 7, wherein a pair of hooks protrudes from the inner side of the cover for retaining the locking block.

13. The computer enclosure as claimed in claim 12, wherein a securing notch is defined in the locking block for the hook engaging thereto.

14. The computer enclosure as claimed in claim 12, wherein a sliding slots is defined beside each hook of the cover, and a ridge corresponding to the securing slot extends through the side face of the locking block.

15. The computer enclosure as claimed in claim 7, wherein a second spring is received between the locking block and the cover.

16. A computer enclosure comprising:
a chassis having a blocking portion; and
a cover attached to the chassis, a pair of hooks protruding from the inner side of the cover, a handle attached to the cover, the cover having a locking block for engaging with the blocking portion, the locking block having a pair of securing notches for the hooks engaging thereto, a spring is disposed between the cover and the locking block, whereby when the handle is pulled in a first direction, the locking block is forced to move along a second direction different from the first direction and disengage from the chassis.

17. The computer enclosure as claimed in claim 16, wherein a pressing tab protrudes from the handle, and the locking block comprises an inclined face for the pressing tab sliding therealong.

18. The computer enclosure as claimed in claim 16, wherein a sliding slot is defined beside each hook of the cover, and a ridge corresponding to the sliding slot extends from the locking block.

19. The computer enclosure as claimed in claim 16, wherein a post protrudes from the cover for the spring disposed around.

20. The computer enclosure as claimed in claim 16, wherein a second spring is disposed between the handle and the cover.
